(19) United States
(12) Patent Application Publication
(10) Pub. No.: US 2006/0068099 A1
(43) Pub. Date: Mar. 30, 2006

(54) Grading PrxCa1-xMnO3 thin films by metalorganic chemical vapor deposition

(75) Inventors: Tingkai Li, Vancouver, WA (US); Lawrence J. Charneski, Vancouver, WA (US); Wei-Wei Zhuang, Vancouver, WA (US); David R. Evans, Beaverton, OR (US); Sheng Teng Hsu, Camas, WA (US)

Correspondence Address: SHARP LABORATORIES OF AMERICA, INC, 5750 NW PACIFIC RIM BLVD, CAMAS, WA, 98642, US

(73) Assignee: Sharp Laboratories of America, Inc.

(21) Appl. No.: 10/957,304

(22) Filed: Sep. 30, 2004

(51) Int. Cl. C23C 16/00

(52) U.S. Cl. 427/248.1; 427/58

(57) ABSTRACT

The present invention discloses a method to achieve grading PCMO thin film for use in RRAM memory devices since the contents of Ca, Mn and Pr in a PCMO film can have great influence on its switching property. By choosing precursors for Pr, Ca and Mn having different deposition rate behaviors with respect to deposition temperature or vaporizer temperature, PCMO thin film of grading Pr, Ca or Mn distribution can be achieved by varying that process condition during deposition. The present invention can also be broadly applied to the fabrication of any multicomponent grading thin film process by varying any of the deposition parameters after preparing multiple precursors to have different deposition rate behaviors with respect to that particular process parameter. The present invention starts with a proper selection of precursors in which the selected precursors have different deposition rates with respect to at least one deposition condition such as deposition temperature or vaporizer temperature. The precursors can then be arranged in different delivery systems, or can be pre-mixed in a proper ratio for use in a delivery system, or in any other combinations such as a mixture of two or three liquid precursors using a direct liquid injection and a separate gaseous precursor delivery system for gaseous process gas. Then by varying the appropriate deposition condition, a grading thin film can be achieved.

This invention generally relates to integrated circuit (IC) memory resistor cell arrays and, more particularly, to a grading PCMO memory resistance cell.

### BACKGROUND OF THE INVENTION

Recent developments of materials that have electrical resistance characteristics that can be changed by external influences have introduced a new kind of non-volatile memory, called RRAM (resistive random access memory). The basic component of a RRAM cell is a variable resistor that can be programmed to have high resistance or low resistance (in two-state memory circuits), or any intermediate resistance value (in multi-state memory circuits). The different resistance values of the RRAM cell represent the information stored in the RRAM circuit. Further, the multistable states of high resistance and low resistance of the RRAM memory need only the applied power to switch the states and not to maintain them. Thus RRAM devices show promise as the leading memory cell structure due to the simplicity of the circuit leading to smaller devices, the non-volatile characteristic of the resistor memory cell, and the stability of the memory state.

The examples of such memory resistor materials are materials having electric pulse-induced-resistive-change (EPIR) effect found in thin film colossal magnetoresistive (CMR) materials such as Pr_{0.7}Ca_{0.3}MnO₃ (PCMO), disclosed in U.S. Pat. No. 6,204,139 of Liu et al., and U.S. Pat. No. 6,473,332 of Ignatiev et al., hereby incorporated by reference. However, the memory resistor materials are still facing various fabrication challenges such as reliable memory operation and relatively large amplitude pulses which may degrade the electrical property of the memory resistor.

It is generally acknowledged that memory resistor material structures and compositions have direct effect on the thin film electrical properties and memory cell operation, and therefore methods to improve the memory resistor materials in RRAM devices such as tailoring crystalline structure, oxygen content distribution, and multilayered structure have been proposed. For example, with the discovery that weak polycrystalline PCMO thin film has resistance switch properties induced by unipolar pulses while highly crystalline film has resistance switch properties induced by bipolar pulses, co-pending application “Methodfor obtaining reversible resistance switches on a PCMO thin film when integrated with a highly crystalline seed layer” of the same inventors, hereby incorporated by reference, has disclosed a sandwiched film of high crystaline and amorphous PCMO layers to change the ways of the resistance modification.

The resistance switch property of a PCMO film also suggests that an uniform PCMO film or a symmetrical device design might not be optimum in realizing memory devices since different electrical field direction as well as different field strength could severely affect the behavior of a memory device employing PCMO resistance material. An asymmetrical memory device where one electrode is larger than the other would reduce the field strength at the larger electrode, and therefore the PCMO film resistance change only at the smaller electrode to ensure that the memory device works properly. This is disclosed in co-pending application “Asymmetric memory cell” of the same inventors, hereby incorporated by reference.

Another way to achieve asymmetrical memory cell is to have geometrically symmetrical, but having physically asymmetrical characteristics. The device physical structure can be practically uniform across the entire film, but the oxygen distribution is controlled through the memory resistor thin film, which in turn affects the device switching properties. For example, an oxygen-rich manganite region has low resistance while an oxygen-deficient manganite region has higher resistance. Thus a sandwiched film of oxygen-rich and oxygen-poor PCMO layers can change the way of resistance modification so that the oxygen-poor manganite region changes resistance in response to an electric field while the resistance of the oxygen-rich manganite region remains constant. This sandwiched layer can be achieved easily by annealing process, and has been disclosed in co-pending application “Oxygen content system and methodfor controlling memory resistance properties” of the same inventors, hereby incorporated by reference.

However, oxygen is mobile in RRAM materials such as PCMO. Therefore, there is a reliability issue if the temperature of the device is raised by either device fabrication process or during circuit operation. Thus it is desirable to fabricate a memory resistor with variable composition across the film thickness for proper memory device operations.

### SUMMARY OF THE INVENTION

The present invention discloses a method to achieve grading PCMO thin film for use in RRAM memory devices since the contents of Ca, Mn and Pr in a PCMO film can have great influence on its switching property. By choosing precursors for Pr, Ca and Mn having different deposition rate behaviors with respect to a deposition parameter such as deposition temperature or vaporizer temperature, PCMO thin films of grading Pr, Ca or Mn distribution can be deposited by varying either that particular deposition parameter during deposition. By choosing the precursors Pr(thd)₃ for Pr, Ca(thd)₂ for Ca, and Mn(thd)₃ for Mn, the deposition rate behaviors of Pr and Mn are shown to be different from that of Ca with respect to substrate temperature and vaporizer temperature. Therefore, PCMO thin films with grading Pr and Mn can be deposited by controlling the substrate temperatures, and PCMO thin films with grading Ca content can be deposited by controlling vaporizer temperatures.

The present invention can also be broadly applied to the fabrication of any multicomponent grading thin film process by varying one of the deposition parameters such as deposition temperature, vaporizer temperature, delivery line temperature, showerhead temperature, plasma energy, lamp heater, etc., after preparing multiple precursors to have different deposition rate behaviors with respect to that process parameter. For example, to deposit a grading component A of a multicomponent thin film comprising components A and B, a precursor PA with a strong deposition rate dependent on deposition temperature and a precursor PB with a weak deposition rate are selected. Then the deposition of an A-grading thin film can be achieved by varying the deposition temperature. Since the deposition rate of component A is strongly dependent on temperature, the change in the deposition temperature during deposition would create a grading distribution of component A in the deposited thin film, and since deposition rate of component B is weakly dependent on temperature, the change in the deposition temperature would not affect the component B, resulting in a more-or-less uniform distribution of component B. Other deposition parameters such as vaporizer temperature can also be used after selecting precursors with appropriate deposition rate behaviors. The graded layers according to the present invention can be step graded, continuous graded or digital graded.

The present invention starts with a proper selection of precursors in which the selected precursors have different deposition rates with respect to a deposition condition. The precursors can be arranged in different delivery systems, or can be pre-mixed in a proper ratio for use in one delivery system, or in any other combinations such as a mixture of two or three liquid precursors using a direct liquid injection and a separate gaseous precursor delivery system for gaseous process gas. Then by varying the appropriate deposition condition, a grading thin film can be achieved.

### BRIEF DESCRIPTION OF THE DRAWINGS

FIG. 1 shows a process chamber employing various delivery systems.

FIG. 2 shows the deposition rates of Ca, Pr and Mn with substrate temperatures.

FIG. 3 shows the deposition rates of Ca, Pr and Mn with vaporizer temperatures.

FIG. 4 shows the EDS pattern of PCMO thin film with grading Ca contents.

FIG. 5 shows the x-ray pattern of PCMO thin film with grading Ca contents on Pt/Ti/SiO₂/Si substrate.

FIG. 6 shows the switching properties of PCMO thin films with grading Ca contents on Pt/Ti/SiO₂/Si substrate.

### DETAILED DESCRIPTION OF THE INVENTION

The present invention discloses a fabrication process to deposit multicomponent grading thin films by varying one of the deposition parameters such as deposition temperature or vaporizer temperature after preparing multiple precursors to have different deposition rate behaviors with respect to that particular process parameter. For example, the present invention can be used to deposit a multicomponent thin film comprising components A and B with an increase concentration of component A at the upper layer portion and a uniform concentration distribution of component B. The process starts with the selection of a precursor PA with a strong deposition rate dependent on deposition temperature (such as higher deposition rate with higher deposition temperature) and a precursor PB with a weak deposition rate (such as a constant deposition rate with respect to the same deposition temperature range). Then the deposition of a thin film with increased concentration of component A can be achieved by increasing the deposition temperature. Since the deposition rate of component A is strongly dependent on temperature, the change in the deposition temperature during deposition would create a grading distribution of component A in the deposited thin film, and since deposition rate of component B is weakly dependent on temperature, the change in the deposition temperature would not affect the component B, resulting in a more-or-less uniform distribution of component B.

The present invention deposition is well suited for chemical vapor deposition (CVD) technique, but is also applicable to other deposition methods. In general, CVD technology has been used in semiconductor processing for a long time, and its characteristics are well known with a variety of precursors available. However, CVD processes still needs major improvements to meet modern technology requirements of new materials and more stringent film qualities and properties, one of which being grading thin films deposition. In CVD, a combination of precursor gases or vapors flows over a substrate such as a wafer surface at an elevated temperature. Reactions of the introduced precursors then take place at the hot substrate surface where deposition occurs. This deposition reaction often requires the presence of an energy source such as thermal energy (in the form of resistive or radiative heating), or plasma energy (in the form of plasma excitation) and is often related directly to the thin film deposition rate. Thus the deposition rate of the thin film is normally influenced by the supplied energy with the degree of influence varied for different reactions or different precursors. Using this principle, the present invention discloses a novel method of deposit grading thin film by providing multiple precursors exhibiting different reaction rates, manifested by different deposition rates, and by varying the supplied energy during the deposition process. The supplied energy is preferably the deposition temperature, which is the substrate temperature in a warm or cold wall process chamber, or the process chamber temperature in a hot wall furnace. The supplied energy is also preferably the vaporizer temperature, which controls the energy supplying to the precursor to convert to vapor form. The supplied energy can also be the delivery line temperature, the showerhead temperature, the plasma energy, a lamp heater, and in general, any energy source provided to the precursors on the path to the thin film reaction.

The deposition temperature, typically the temperature of the wafer surface, is an important factor in CVD deposition, as it affects the deposition reaction of the precursors and also the deposition rate, the film quality, and the uniformity of deposition over the large wafer surface. CVD typically requires high temperature, in the order of 400 to 800° C. To lower the deposition temperature, the precursors can be excited with an external energy such as a plasma in plasma enhanced chemical vapor deposition (PECVD) process. The wafer temperature in CVD processes are chosen to optimize the desired film compositions and properties, but in general, much of the film properties and compositions are dependent on the wafer temperature. For example, CVD at lower temperature tends to produce low quality films in terms of uniformity and impurities.

Taking advantages of the strong dependent of deposition rates of CVD deposition processes with temperature, the present invention can achieve a grading thin film property by properly selecting precursors and varying the deposition temperature during deposition. The selection of precursors is thus an important aspect in the present invention grading thin film process in which the multiple precursors are selected having different deposition rate behaviors with respect to deposition temperature so that when mixing together, either in the deposition chamber or forming a precursor mixture prior to delivery, the resulting thin film can have a grading property by varying the deposition temperature. The variation of the deposition temperature can be in the range of 100 to 600° C., but preferably in the range of about 200° C., and more preferably about 100° C. or so. The smaller the temperature variation, the faster for the temperature change, and thus better the processing throughput. In addition to the present invention requirement of having different deposition rate behaviors with respect to deposition temperature, the precursors suitable for CVD processes are also preferably chosen to satisfy other requirements, such as rapid reaction with minimum impurity contamination, sufficient vapor pressure at deposition temperatures, high temperature thermal stability, stability under ambient conditions, and minimal toxicity. Traditionally, precursors used in semiconductor processes are gaseous source, containing proper amounts of suitably reactive chemicals. For novel materials, it is increasingly difficult to find suitable gaseous source precursors, and thus more and more liquid precursors have been used, especially in the area of metal-organic chemical vapor deposition (MOCVD). Solids can also be used as sources of vapor in CVD processes, however, due to various problems of reproducibility, controllability, surface contamination, and thermal decomposition, solid source precursors are not readily available for many CVD processes. Thermal decomposition is also a potential problem for liquid sources, but its effect may be minimized by rapid or flash vaporization. This can be accomplished by metering the liquid at room temperature into a hot region (called a vaporizer) in which the liquid vaporizes quickly. In such direct liquid injection (DLI) system, the liquid is heated only at the point of use with the liquid reservoir remaining at room temperature, and therefore reducing thermal decomposition problem even from thermally sensitive liquids. Also solid sources can be used in a DLI system if proper dissolved in a suitable liquid solvent.

In another embodiment of the invention using a DLI system, the present invention can achieve a grading thin film property by properly selecting precursors and varying the vaporizer temperature during deposition, employing another advantage of the DLI system of reproducible film composition using multiple precursors, even if the individual precursors differ in volatility. The multiple precursor sources are accurately mixed in a single multicomponent precursor medium as a “cocktail” including all of the component reagents and an optional single solvent. The single multicomponent precursor medium is then flash vaporized in a vaporizer and the resulting vapor is delivered to the reactor. To achieve the grading thin film property according to the present invention, the precursors chosen in the mixture are selected to have different deposition rate behaviors with respect to the vaporizer temperature. By varying the vaporizer temperature, the resulting thin film can achieve grading composition according to the present invention. The variation of the vaporizer temperature can be in the range of 10 to 200° C., but preferably in the range of about 100° C., and more preferably about 50° C. or so. Similar to the change in deposition temperature, the smaller the vaporozer temperature variation, the faster for the temperature change, and thus better the processing throughput. The preferred embodiment of varying the deposition temperature can also be applied to this embodiment if the precursors in the mixture are selected to have different deposition rate behaviors with respect to the deposition temperature. In addition to the present invention requirement of having different deposition rate behaviors, the selected precursors are preferably chosen to satisfy other requirements such as similar volatility and decomposition behaviors, or in the event that similar volatility and decomposition behaviors cannot be achieved, compensation for excess precursor of relatively high volatility to control the proper composition of the thin film. Further, the precursor mixture is preferably dissolved in a proper solvent since the solvent will be a major constituent of the chemical solution. The solvent utilized for delivering the precursors may comprise any suitable solvent species, or combination of solvent species, compatible with the selected precursors and highly capable of dissolving precursor compounds. The solvents are preferably tetrahydrofuran, alkyl acetate, butyl acetate, polyethylene glycol dimethyl ether, tetraglyme, glymes, aliphatic hydrocarbons, aromatic hydrocarbons, ethers, esters, alkyl nitrites, alkanols, amines, polyamines, isopropanol, alcohols, glycols, tetrathiocyclodecane, or conventional organic solvent such as hexane, toluene and pentane. The solvent may be employed as single species medium or solvent mixtures. For example, an 3:1 by volume mixture of butylether and tetraglyme may be used.

The present invention method of grading thin film deposition can also be applied to other deposition conditions such as the vapor delivery line temperature, the showerhead temperature, the plasma energy, a lamp heater, and in general, any energy source provided to the precursors on the path to the thin film reaction. The only requirement is that the precursors are selected to have different deposition rate behaviors with respect to that particular deposition condition.

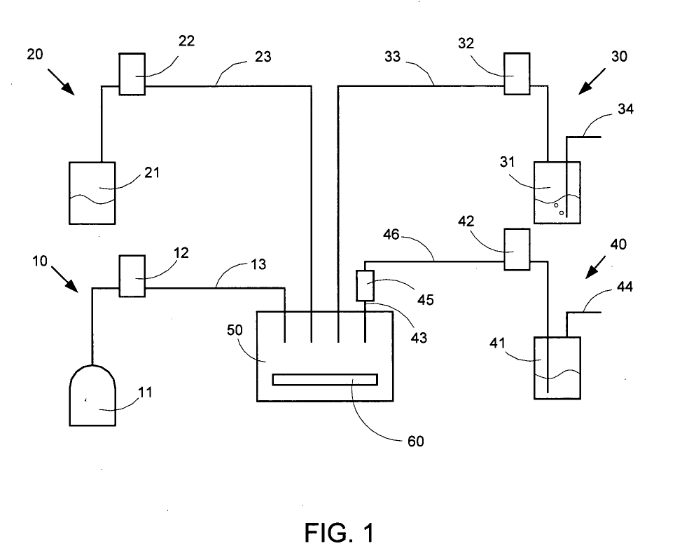

FIG. 1 shows a process chamber using a plurality of precursor delivery systems according to the present invention. The process chamber comprises a gaseous delivery system 10, a liquid vapor draw delivery system 20, a liquid bubbling delivery system 30 and a direct liquid injection 40, delivering to a process chamber 50 containing a substrate 60. The gaseous delivery system 10 comprises a compressed gaseous precursor cylinder 11, delivering gaseous precursor through the gaseous delivery line 13 to the process chamber 50 with the gaseous precursor flow controlled by a flow meter 12. For gaseous process gases such as oxygen, ammonia, silane, etc., the gaseous precursor delivery system shown above is the typical configuration. For liquid precursor, the simplest form of liquid precursor delivery system is to draw the vapor from the liquid precursor, similar to gaseous precursors. This technique works well with high volatile liquid with high vapor pressure, plus the liquid precursor and the vepor delivery line can also be heat up to achieve the necessary vapor pressure and to prevent condensation. The liquid vapor draw delivery system 20 comprises a liquid precursor container 21, delivering precursor vapor through the vapor delivery line 23 to the process chamber 50 with the precursor vapor flow controlled by a flow meter 22. Another technique of liquid precursor delivery is bubbling by using a non-reactive precursor such as argon or nitrogen, often called a carrier gas, to bubble through the liquid precursor. The carrier gas then carries the vapor precursor to the processing chamber. The liquid bubbling delivery system 30 is similar to the vapor draw delivery system 20 with the addition of a carrier line 34 to increase the inlet pressure, comprising a liquid precursor container 31, delivering precursor vapor through the vapor delivery line 33 to the process chamber 50 with the precursor vapor flow controlled by a flow meter 32.

However, to have high deposition rate with low vapor pressure precursors, a direct liquid injection system as described above is much more desirable. Basic components of a direct liquid injection system is a liquid delivery line, a vaporizer and a vapor delivery line. The liquid delivery line carries the liquid precursor from the liquid container to the vaporizer. The flow rate of the liquid is controlled by a liquid flow controller, similar to a mass flow controller. The vaporizer converts the liquid precursor into vapor form and the vapor delivery line delivers the precursor vapor onto the wafer substrate. A carrier gas is normally used in the vaporizer to carry the precursor vapor to the substrate. In some applications, a reactive precursor could take place of the carrier gas, performing the carrying function together with a chemical reaction. The direct liquid injection delivery system 40 comprises a liquid precursor container 41, delivering precursor liquid through the liquid delivery line 46 with the precursor liquid flow controlled by a liquid flow meter 42, to a vaporizer 45 to a vapor delivery line 43 to the process chamber 50. The multiple precursor reaction is accomplished inside the process chamber and therefore to ensure good film deposition, proper chamber designs (not shown) such as substrate 60 rotation, showerhead delivery, concentric pumping, plasma incorporation, etc. might be needed. Multiple precursors mixing can be accomplished prior to deposition and stored in the precursor containers of 11, 21, 31, or 41.

The present invention starts with a proper selection of precursors in which the selected precursors have different deposition rates with respect to a deposition condition such as deposition temperature, vaporizer temperature. The precursors can be arranged in different delivery systems, or can be pre-mixed in a proper ratio for use in a delivery system, or in any other combinations such as a mixture of two or three liquid precursors using a direct liquid injection and a separate gaseous precursor delivery system for gaseous process gas. Then by varying the appropriate deposition condition, a grading thin film can be achieved.

The present invention is particularly suited for memory materials such as PCMO. Such memory materials are typically materials having electric pulse-induced-resistive-change (EPIR) effect found in perovskite materials having magnetoresistive effect such as the manganite perovskite materials of the Re₁₋ₓAeₓMnO₃ structure (Re: rare earth elements, Ae: alkaline earth elements) such as Pr_{0.7}Ca_{0.3}MnO₃ (PCMO), La_{0.7}Ca_{0.3}MnO₃ (LCMO), Nd_{0.7}Sr_{0.3}MnO₃ (NSMO). The rare earth elements are La, Ce, Pr, Nd, Pm, Sm, Eu, Gd, Tb, Dy, Ho, Er, Tm, Yb, and Lu. The alkaline earth metals are Be, Mg, Ca, Sr, Ba, and Ra. Suitable perovskite materials further include magnetoresistive materials and high temperature superconductivity (HTSC) materials such as PrCaMnO (PCMO), LaCaMnO (LCMO), LaSrMnO (LSMO), LaBaMnO (LBMO), LaPbMnO (LPMO), NdCaMnO (NCMO), NdSrMnO (NSMO), NdPbMnO (NPMO), LaPrCaMnO (LPCMO), and GdBaCoO (GBCO). HTSC materials can store information by the their stable magnetoresistance state, which can be changed by an external magnetic or electric field, and the information can be read by magnetoresistive sensing of such state. HTSC materials such as PbZrₓTi₁₋ₓO₃, YBCO (Yttrium Barium Copper Oxide, YBa₂Cu₃O₇ and its variants), have their main use as a superconductor, but since their conductivity can be affected by an electrical current or a magnetic field, these HTSC materials can also be used as variable resistors in nonvolatile memory cells.

Following is an example of the processes for grading PCMO thin film deposition using liquid delivery MOCVD techniques in which the deposited PCMO film can have a grading Ca, Pr or Mn contents. Using the graded doped PCMO thin film the reliability of the RRAM memory resistor can be greatly improved since the contents of Ca and Pr in a PCMO film can have a great influence on its switching property. In addition these ions are stable in PCMO in the moderate temperature region, and therefore, the modulation of the Ca or Pr content in RRAM memory cell may enable the memory cell to be programmed by either unipolar or bipolar process. Plus the RRAM device will be asymmetric and does not require a high programming voltage.

The precursors chosen for PCMO deposition are solid organometallic compounds, Pr(thd)₃, Ca(thd)₂, and Mn(thd)₃, plus an oxygen gaseous precursor. The organic solvent medium comprises butylether and tetraglyme, mixed in the volume ratio of 3:1, and dissolving 1 N metal of each precursors Pr(thd)₃, Ca(thd)₂, Mn(thd)₃ with ratio around 0.9:0.6:1. The precursor solutions have a concentration of 0.1 M/L of metals for each component Pr, Ca and Mn. The solution was delivered by a liquid flow meter at a rate of 0.1-0.5 ml/minutes into a vaporizer at temperature in the range of 240-260° C. The precursor mixture is evaporated in the vaporizer and then transported to a CVD chamber for PCMO thin film deposition. The feed line after the vaporizer was kept at 240-280° C. to prevent condensation. The substrate used is Pt/(Ti or TiN or TaN)/SiO₂/Si and Ir/(Ti or TiN or TaN)/SiO₂/Si. The deposition temperature is from 400 to 500° C. and the deposition pressure is about 1-5 Torr. The oxygen partial pressures is about 20-30%. With these conditions, the deposition time is about 20 to 60 minutes depending on film thickness. The compositions of PCMO thin films are then measured by EDX and phases of the PCMO thin films are identified using x-ray diffraction.

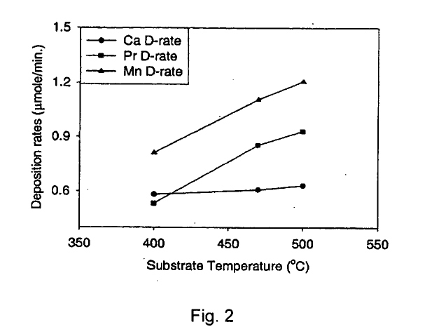

The precursors are first chosen so that their deposition rates vary with selected deposition process condition. FIG. 2 shows the deposition rates of Ca, Pr, and Mn as a function of substrate temperatures, varying from 400 to 500° C. The deposition rate behaviors of Pr and Mn are different from that of Ca with respect to substrate temperature in which the deposition rates of Pr and Mn increase and the deposition rate of Ca is almost constant with increasing substrate temperatures. Therefore, the PCMO thin films with grading Pr and Mn can be deposited by controlling the substrate temperatures.

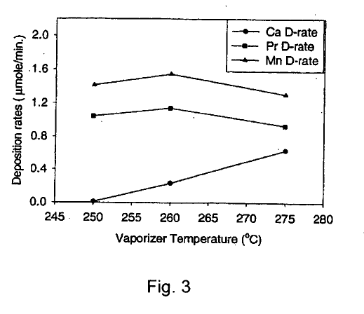

FIG. 3 shows the deposition rates of Ca, Pr and Mn as a function of vaporizer temperatures, varying from 250 to 275° C. The deposition rate behavior of Ca is different from those of Pr and Mn with respect to vaporizer temperature in which the deposition rate of Ca increases significantly but the deposition rates of Pr and Mn change little with increasing vaporizer temperatures. Therefore, the PCMO thin films with grading Ca content can be deposited by controlling vaporizer temperatures.

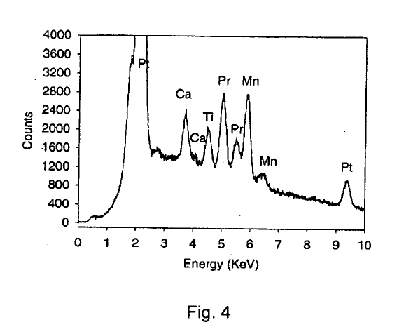

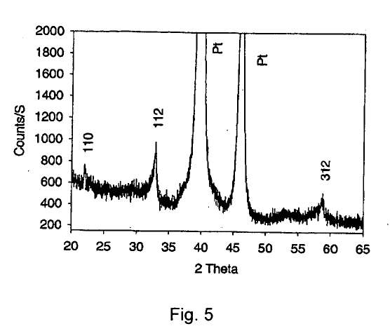

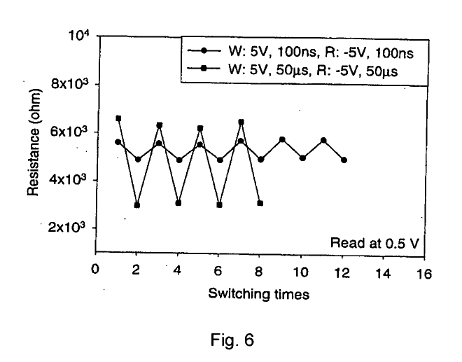

FIG. 4 shows the EDS pattern of the PCMO thin film with grading Ca contents ratio from around 0.2 to 0.4 fabricated by controlling the vaporizer temperatures. The deposition temperature is kept at 405° C. and the vaporizer temperature is slowly changed from 265° C. to 275° C. The total composition of the grading PCMO thin film is around Pr_{0.71}Ca_{0.29}Mn_{1.02}O₃. FIG. 5 shows the x-ray pattern of PCMO thin film with grading Ca contents on a Pt/Ti/SiO₂/Si wafer. The x-ray pattern shows small PCMO 110, 112 and 312 peaks, which means the PCMO thin films with grading Ca contents have a small grain. FIG. 6 shows the switching properties of the PCMO thin film with grading Ca contents, showing only bipolar switching with stable switching properties. And with increasing pulse time, the resistance change ratio increases.

Thus a novel method to fabricate grading thin film has been disclosed, together with an application for grading PCMO for memory devices. Although illustrated and described with reference to certain specific fabrication processes, the present invention is nevertheless not intended to be limited to the details shown. The general process of semiconductor fabrication has been practiced for many years, and due to the multitude of different ways of fabricating a device or structure, various modifications may be made in the fabrication process details without departing from the meaning of the invention. It will be appreciated that though preferred embodiments of the invention have been disclosed, further variations and modifications thereof may be made within the scope and range of the invention as defined in the appended claims.

What is claimed is:

1. A method for depositing a grading thin film on a substrate positioned inside a process chamber, the method comprising:
delivering a plurality of precursors to the process chamber;
varying a deposition parameter, the deposition parameter influencing the amount of energy supplied to the precursors or to the reaction of the precursors;
wherein at least two of the precursors have different deposition rate behaviors with respect to the deposition parameter.

2. A method as in claim 1 wherein the deposition parameter is the deposition temperature.

3. A method as in claim 1 wherein the delivery of the precursors comprises a vaporizer to convert the precursors to vapor form and the deposition parameter is the vaporizer temperature.

4. A method as in claim 1 wherein the precursors are delivered separately to the process chamber.

5. A method as in claim 1 wherein at least two of the precursors are pre-mixed into a mixture and the mixture is delivered to the process chamber.

6. A method as in claim 1 wherein the delivery of the precursors comprises a direct liquid injection delivery system, a gaseous precursor delivery system, a vapor draw precursor delivery system, or a liquid bubbling precursor delivery system.

7. A method as in claim 1 wherein the delivery of the precursors comprises a direct liquid injection delivery system comprising a vaporizer and the deposition parameter is the vaporizer temperature.

8. A method as in claim 1 wherein the two precursors having different deposition rate behaviors with respect to the deposition parameter are metal-organic precursors.

9. A method for depositing a grading memory resistor thin film for RRAM applications, the thin film being deposited on a substrate positioned inside a process chamber, the method comprising:
delivering a plurality of precursors to the process chamber;
varying a deposition parameter, the deposition parameter influencing the amount of energy supplied to the precursors or to the reaction of the precursors;
wherein at least two of the precursors have different deposition rate behaviors with respect to the deposition parameter.

10. A method as in claim 9 wherein the resistor thin film including manganite from a material selected from the group including perovskite-type manganese oxides with the general formula RE₁₋ₓAEₓMnO_{y}, where RE is a rare earth ion and AE is an alkaline-earth ion, with x in the range between 0.1 and 0.5 and y in the vicinity of 3.

11. A method as in claim 9 wherein the deposition parameter is the deposition temperature.

12. A method as in claim 9 wherein the delivery of the precursors comprises a vaporizer to convert the precursors to vapor form and the deposition parameter is the vaporizer temperature.

13. A method for depositing a grading PCMO thin film on a substrate positioned inside a process chamber, the method comprising:
delivering a plurality of precursors to the process chamber, the precursors comprising an oxygen-containing precursor and a precursor mixture of a Pr-containing precursor, a Ca-containing precursor and a Mn-containing precursor;
varying a deposition parameter, the deposition parameter influencing the amount of energy supplied to the precursors or to the reaction of the precursors;
wherein at least two of the precursors containing Pr, Ca and Mn have different deposition rate behaviors with respect to the deposition parameter.

14. A method as in claim 13 wherein the two precursors exhibit different deposition rate behaviors with respect to the deposition parameter when delivered together with the oxygen-containing precursor.

15. A method as in claim 13 wherein the Pr-containing precursor, the Ca-containing precursor, or the Mn-containing precursor is a liquid metal-organic precursor or a solid metal-organic precursor dissolved in a solvent.

16. A method as in claim 13 wherein the Pr-containing precursor is Pr(thd)₃, the Ca-containing precursor is Ca(thd)₂, and the Mn-containing precursor is Mn(thd)₃.

17. A method as in claim 13 wherein the ratio of the Pr-containing precursor, the Ca-containing precursor is Ca(thd)₂, and the Mn-containing precursor is around 0.9:0.6:1.

18. A method as in claim 13 wherein the precursor mixture comprising the Pr-containing precursor, the Ca-containing precursor and the Mn-containing precursor is dissolved in a solvent.

19. A method as in claim 18 wherein the solvent is a mixture of butylether and tetraglyme.

20. A method as in claim 18 wherein the solvent is a mixture of 3:1 volume of butylether and tetraglyme.

21. A method as in claim 13 wherein the deposition parameter is the temperature of the substrate.

22. A method as in claim 21 wherein the range of the temperature variation is about 200° C.

23. A method as in claim 13 wherein the delivery of the precursors comprises a direct liquid injection delivery system comprising a vaporizer and the deposition parameter is the vaporizer temperature.

24. A method as in claim 23 wherein the range of the temperature variation is about 50° C.
